(19) United States
(12) Patent Application Publication
(10) Pub. No.: US 2023/0400511 A1
(43) Pub. Date: Dec. 14, 2023

(54) Pin Testing System for Multi-Pin Chip and Method Thereof

(71) Applicants: Inventec (Pudong) Technology Corporation, Shanghai (CN); Inventec Corporation, Taipei City (TW)

(72) Inventor: Jin-Dong Zhao, Shanghai (CN)

(21) Appl. No.: 17/843,837

(22) Filed: Jun. 17, 2022

(30) Foreign Application Priority Data
Jun. 10, 2022 (CN) 202210654542.5

(51) Int. Cl. G01R 31/317

(52) U.S. Cl. CPC G01R 31/31715; G01R 31/31713

(57) ABSTRACT

A pin testing system for a multi-pin chip and method thereof are disclosed. In the system, a chip testing circuit board includes a testing circuit, a to-be-tested chip fixture, a testing chip and a JTAG port, each pin of the testing chip is electrically connected to a corresponding pin of the to-be-tested chip fixture through the testing circuit. The JTAG port, the testing chip and the to-be-tested chip fixture are serially connected to form a JTAG link through the testing circuit, the testing device, the JTAG controller and the chip testing circuit board are serially connected, the testing device generates a testing signal to test each of the pins of the to-be-tested chip through the JTAG controller, and a testing result for each of the pins is transmitted to the testing device, so that the testing on the pins of the to-be-tested chip is completed.

### CROSS-REFERENCE TO RELATED APPLICATION

This application claims the benefit of Chinese Application Serial No. 202210654542.5, filed Jun. 10, 2022, which is hereby incorporated herein by reference in its entirety.

### BACKGROUND OF THE INVENTION

### 1. Field of the Invention

The present invention is related to a testing system and method thereof, and more particularly to a pin testing system for multi-pin chip and method thereof; in the pin testing system of the present invention, a JTAG port, a testing chip and a to-be-tested chip fixture are serially connected to form a JTAG link through a testing circuit, and a testing device performs testing on pins of a to-be-tested chip on the chip testing circuit board through a JTAG controller.

### 2. Description of the Related Art

The conventional testing method for complex multi-pin chips performs quality confirmation of the appearance of the chip and solder ball oxidation, and is also necessary to perform functional testing on complex pin chips. Generally, the conventional pin function testing for a multi-pin chip measures a yield based on a small batch of samples only, but the conventional testing method has problems of high testing cost, long testing time and inconvenience for batch testing.

According to above-mentioned contents, it is necessary to develop an improved technical solution to solve the conventional problems, to solve the conventional technology problems of high testing cost, long testing time, and inconvenience for batch testing.

### SUMMARY OF THE INVENTION

An objective of the present invention is to disclose a pin testing system for a multi-pin chip and method thereof, to solve the conventional technical problems of high testing cost, long testing time, and inconvenience for batch testing.

In order to achieve the objective, the present invention provides a pin testing system for a multi-pin chip; the pin testing system includes a chip testing circuit board, a JTAG controller and a testing device, and the chip testing circuit board includes a to-be-tested chip fixture, a testing chip and a JTAG port.

The to-be-tested chip fixture is electrically connected to the testing circuit and configured to clamp and fasten a to-be-tested chip. The testing chip is electrically connected to the testing circuit and having pins, wherein each of the pins of the testing chip is electrically connected to a corresponding one of pins of the to-be-tested chip fixture through the testing circuit. The JTAG port, the testing chip and the to-be-tested chip fixture are serially connected to form a JTAG link through the testing circuit. The JTAG controller is electrically connected to the JTAG port. The testing device is electrically connected to the JTAG controller and configured to generate a testing signal. The testing device transmits the testing signal to the JTAG controller, the JTAG controller transmits the testing signal to the chip testing circuit board, the chip testing circuit board performs testing on one of the pins of the to-be-tested chip based on the testing signal, and transmits a testing result to the testing device, so as to complete the testing on the pins of the to-be-tested chip.

In order to achieve the objective, the present invention provides a pin testing method for a multi-pin chip, and the pin testing method includes steps of: providing a chip testing circuit board comprising a testing circuit, a to-be-tested chip fixture, a testing chip and a JTAG port; electrically connecting the to-be-tested chip fixture to the testing circuit, and clamping and fastening a to-be-tested chip, by the to-be-tested chip fixture; electrically connecting the testing chip to the testing circuit, wherein each of pins of the testing chip is electrically connected to a corresponding one of pins of the to-be-tested chip fixture through the testing circuit; serially connecting the JTAG port, the testing chip and the to-be-tested chip fixture to form a JTAG link, by the testing circuit; electrically connecting a JTAG controller to the JTAG port; electrically connecting a testing device to the JTAG controller, wherein the testing device is configured to generate a testing signal; wherein the testing device transmits the testing signal to the JTAG controller, the JTAG controller transmits the testing signal to the chip testing circuit board, the chip testing circuit board performs testing on one of the pins of the to-be-tested chip based on the testing signal, and transmits a testing result to the testing device, so as to complete the testing on the pins of the to-be-tested chip.

According to above-mentioned content, the difference between the present invention and the conventional technology is that, in the present invention, the chip testing circuit board includes the testing circuit, the to-be-tested chip fixture, the testing chip and the JTAG port, each of the pins of the testing chip is electrically connected to the corresponding one of the pins of the to-be-tested chip fixture through the testing circuit. The JTAG port, the testing chip and the to-be-tested chip fixture are serially connected to form the JTAG link through the testing circuit, the testing device, the JTAG controller and the chip testing circuit board are serially connected, the testing device generates the testing signal to test each of the pins of the to-be-tested chip through the JTAG controller, and the testing result for each of the pins is transmitted to the testing device, so that the testing on the pins of the to-be-tested chip can be completed.

By the above-mentioned technical solution, the present invention is able to achieve the technical effect of providing convenient and quick function testing on pins of a multi-pin chip.

### BRIEF DESCRIPTION OF THE DRAWINGS

The structure, operating principle and effects of the present invention will be described in detail by way of various embodiments which are illustrated in the accompanying drawings.

FIG. 1 is a system block diagram of a pin testing system for a multi-pin chip, according to the present invention.

FIG. 2 is a perspective view of a to-be-tested chip fixture for testing pins of a multi-pin pin, according to the present invention.

FIG. 3 is a schematic diagram of a JTAG link for testing pins of a multi-pin chip, according to the present invention.

FIG. 4 is a schematic view of an operation of performing testing on a to-be-tested chip, according to the present invention.

FIG. 5 is a flowchart of a pin testing method for a multi-pin chip, according to the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the scope of the present invention in any way. Further modifications to the disclosed embodiments, as well as other embodiments, are also included within the scope of the appended claims.

These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts. As used herein, the singular forms “a”, “an” and “the” are intended to include the plural forms as well, unless the context clearly indicates otherwise.

It is to be acknowledged that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the words “comprise” and “include”, and variations such as “comprises”, “comprising”, “includes”, or “including”, will be acknowledged to imply the inclusion of stated elements but not the exclusion of any other elements.

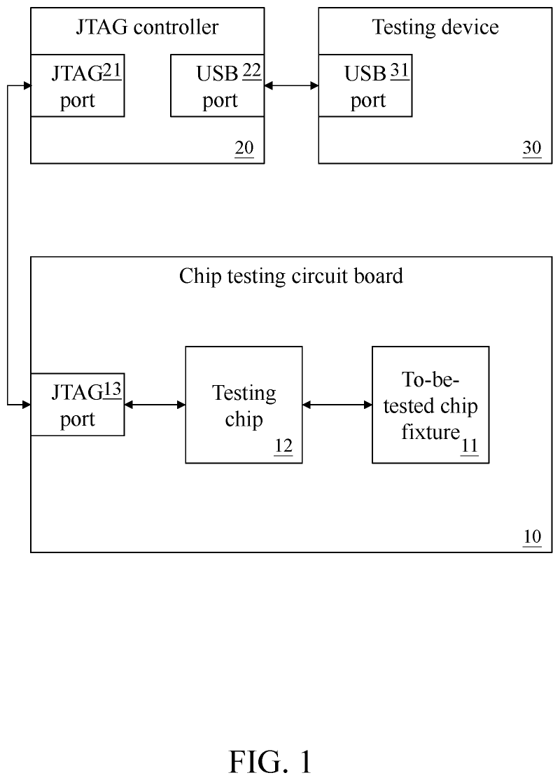

The pin testing system of the present invention will be illustrated in the following paragraphs. Please refer to FIG. 1, which is a system block diagram of a pin testing system for a multi-pin chip, according to the present invention.

The pin testing system includes a chip testing circuit board 10, a JTAG controller 20 and a testing device 30; the chip testing circuit board 10 includes a to-be-tested chip fixture 11, a testing chip 12 and a JTAG port 13.

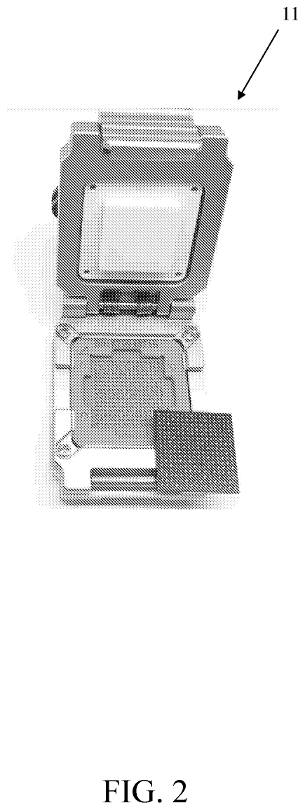

The chip testing circuit board 10 includes a testing circuit, the to-be-tested chip fixture 11 of the chip testing circuit board 10 is electrically connected to the testing circuit, and configured to clamp and fasten a to-be-tested chip. The to-be-tested chip fixture 11 is shown in FIG. 2, which is a perspective view of the to-be-tested chip fixture for testing pins of a multi-pin pin, according to the present invention.

The testing chip 12 is electrically connected to the testing circuit, each of pins of the testing chip 12 is electrically connected to a corresponding one of pins of the to-be-tested chip fixture 11 through the testing circuit. When the to-be-tested chip is clamped and fastened by the to-be-tested chip fixture 11, each pin of the testing chip 12 is electrically connected to the corresponding pin of the to-be-tested chip through the testing circuit. It should be noted that the to-be-tested chip clamped and fastened by the to-be-tested chip fixture 11 is the same type of chip as the testing chip 12.

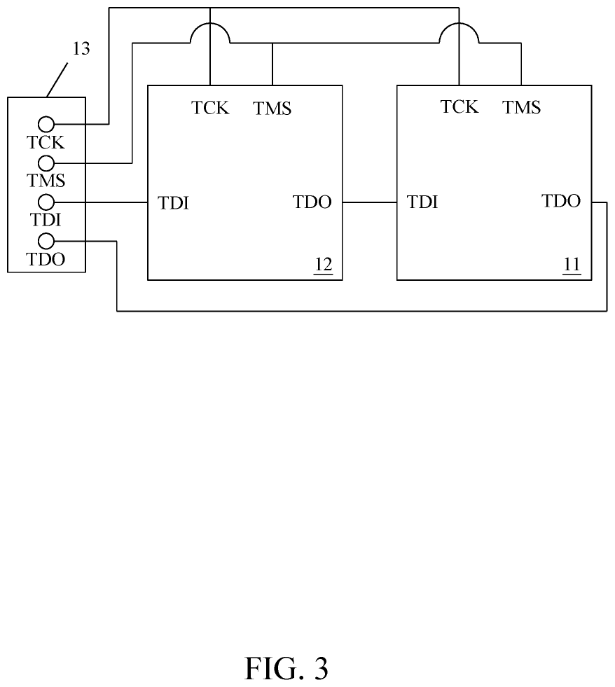

Please refer to FIG. 3, which is a schematic diagram of a JTAG link for testing pins of a multi-pin chip, according to the present invention.

Based on the clamped and fastened to-be-tested chip, the to-be-tested chip fixture 11 has a test data input (TDI) pin, a test data output (TDO) pin, a test clock (TCK) pin and a test mode select (TMS) pin; the testing chip 12 has a TDI pin, a TDO pin, a TCK pin and a TMS pin; the JTAG port 13 has a TDI pin, a TDO pin, a TCK pin and a TMS pin.

The TCK pin of the to-be-tested chip fixture 11, the TCK pin of the testing chip 12, and the TCK pin of the JTAG port 13 are connected to each other; the TMS pin of the to-be-tested chip fixture 11, the TMS pin of the testing chip 12, and the TMS pin of the JTAG port 13 are connected to each other.

The TDI pin of the JTAG port 13 is connected to the TDI pin of the testing chip 12, the TDO pin of the testing chip 12 is connected to the TDI pin of the to-be-tested chip fixture 11, the TDO pin of the to-be-tested chip fixture 11 is connected to the TDO pin of the JTAG port 13, so that the JTAG port 13, the testing chip 12 and the to-be-tested chip fixture 11 are serially connected to form a JTAG link through the testing circuit.

The JTAG controller 20 includes a JTAG port 21 and a universal serial bus (USB) port 22, the testing device 30 includes a USB port 31, the JTAG port 21 of the JTAG controller 20 is electrically connected to the JTAG port 13 of the chip testing circuit board 10 through a JTAG connection line, the USB port 31 of the testing device 30 is electrically connected to the USB port 22 of the JTAG controller 20 through a USB connection line. In an embodiment, the above-mentioned testing device 30 can be, for example, a general computer or a notebook computer, but these examples are merely for exemplary illustration and the application field of the present invention is not limited to these examples.

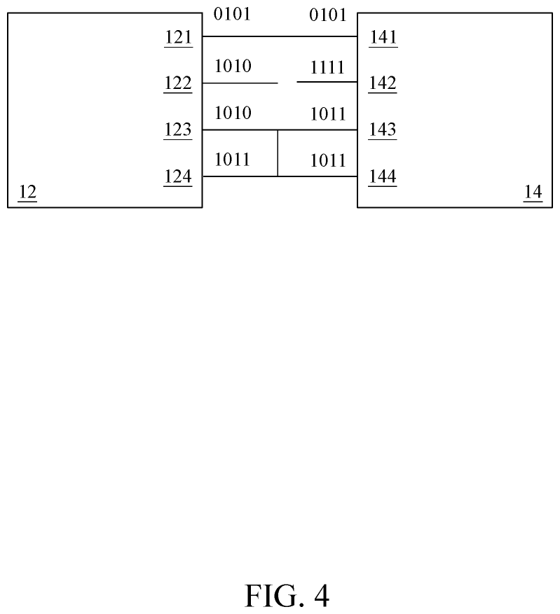

Please refer to FIG. 4, which is a schematic view of an operation of performing testing on a to-be-tested chip, according to the present invention.

The testing device 30 generates and transmits a testing signal to the JTAG controller 20, the JTAG controller 20 converts the testing signal into the testing signal with a JTAG format for boundary scan (BS) testing, and the JTAG controller 20 transmits the converted testing signal to the chip testing circuit board 10, the chip testing circuit board 10 performs testing on each of the pins of the to-be-tested chip based on the testing signal, and a testing result is transmitted to the testing device, so as to complete the testing on the pins of the to-be-tested chip.

As shown in FIG. 4, the testing signal for the first pin 121 of the testing chip 12 is “0101”, the testing result for the first pin 141 of the to-be-tested chip 14 is “0101”, the testing result received by the testing device 30 from the first pin 141 of the to-be-tested chip 14 is “0101”, which is the same as the testing signal “0101”, so the first pin 141 of the to-be-tested chip 14 is normal.

As shown in FIG. 4, the testing signal on the second pin 122 of the testing chip 12 is “1010”, the testing result for the second pin 142 of the to-be-tested chip 14 is “1111”, the testing result received by the testing device 30 from the second pin 142 of the to-be-tested chip 14 is “1111”, which is not affected by the testing signal “1010”, so the testing result of the second pin 142 of the to-be-tested chip 14 indicates that an open-circuit abnormality occurs on the second pin 142.

As shown in FIG. 4, the testing signal for the third pin 123 of the testing chip 12 is “1010” and the testing signal for the fourth pin 124 of the testing chip 12 is “1011”, the testing result for the third pin 143 of the to-be-tested chip 14 is “1011” and the testing result for the fourth pin 144 of the to-be-tested chip 14 is “1011”, and the testing results received by the testing device 30 from the third pin 143 and the fourth pin 144 of the to-be-tested chip 14 are “1011” and “1011”, respectively.

The testing signals for the third pin 143 and the fourth pin 144 of the to-be-tested chip 14 are “1010” and “1011”, respectively, and the testing results from the third pin 143 and the fourth pin 144 of the to-be-tested chip 14 are “1011” and “1011”, respectively, so the testing device 30 can determine that short-circuit abnormality occurs on the third pin 143 and the fourth pin 144 of the to-be-tested chip 14 based on the testing results.

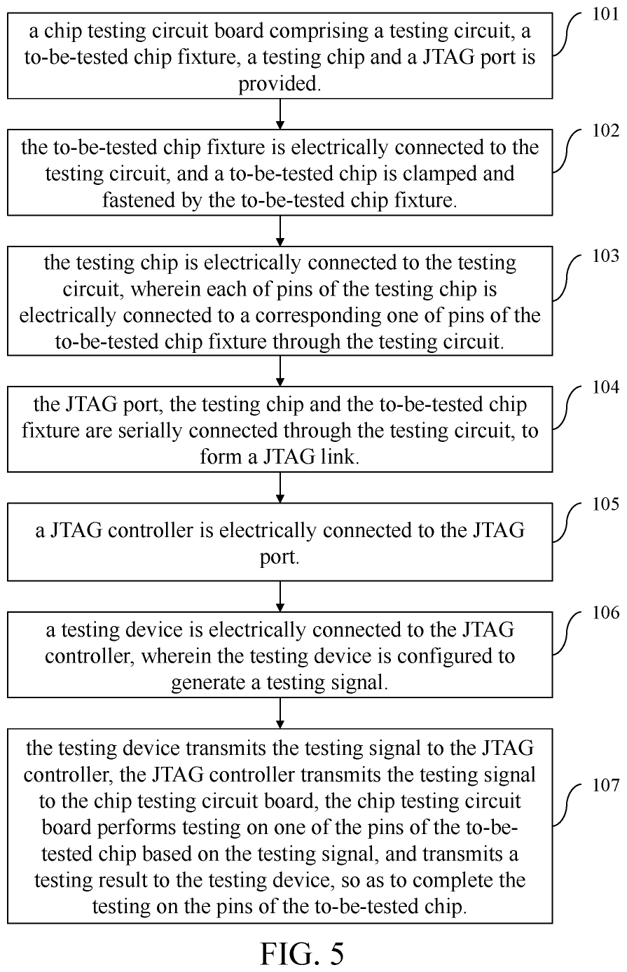

The operation of a pin testing method of the present invention will be illustrated in the following paragraphs. Please refer to FIG. 5, which is a flowchart of a pin testing method for a multi-pin chip, according to the present invention.

As shown in FIG. 5, the pin testing method includes the following steps. In a step 101, a chip testing circuit board comprising a testing circuit, a to-be-tested chip fixture, a testing chip and a JTAG port is provided. In a step 102, the to-be-tested chip fixture is electrically connected to the testing circuit, and a to-be-tested chip is clamped and fastened by the to-be-tested chip fixture. In a step 103, the testing chip is electrically connected to the testing circuit, wherein each of pins of the testing chip is electrically connected to a corresponding one of pins of the to-be-tested chip fixture through the testing circuit. In a step 104, the JTAG port, the testing chip and the to-be-tested chip fixture are serially connected through the testing circuit, to form a JTAG link. In a step 105, a JTAG controller is electrically connected to the JTAG port. In a step 106, a testing device is electrically connected to the JTAG controller, wherein the testing device is configured to generate a testing signal. In a step 107, the testing device transmits the testing signal to the JTAG controller, the JTAG controller transmits the testing signal to the chip testing circuit board, the chip testing circuit board performs testing on one of the pins of the to-be-tested chip based on the testing signal, and transmits a testing result to the testing device, so as to complete the testing on the pins of the to-be-tested chip.

According to above-mentioned contents, the difference between the present invention and the conventional technology is that, in the present invention, the chip testing circuit board includes the testing circuit, the to-be-tested chip fixture, the testing chip and the JTAG port, each of the pins of the testing chip is electrically connected to the corresponding one of the pins of the to-be-tested chip fixture through the testing circuit. The JTAG port, the testing chip and the to-be-tested chip fixture are serially connected to form the JTAG link through the testing circuit, the testing device, the JTAG controller and the chip testing circuit board are serially connected, the testing device generates the testing signal to test each of the pins of the to-be-tested chip through the JTAG controller, and the testing result for each of the pins is transmitted to the testing device, so that the testing on the pins of the to-be-tested chip can be completed.

By the above-mentioned technical solution, the present invention is able to solve the conventional technical problem that the conventional complex multi-pin chip testing method has high testing cost, long testing time, and inconvenience for batch testing, so as to achieve the technical effect of providing convenient and quick function testing on pins of a multi-pin chip.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A pin testing system for a multi-pin chip, comprising:
a chip testing circuit board has a testing circuit, the chip testing circuit board comprising
a to-be-tested chip fixture, electrically connected to the testing circuit and configured to clamp and fasten a to-be-tested chip;
a testing chip, electrically connected to the testing circuit and having pins, wherein each of the pins of the testing chip is electrically connected to a corresponding one of pins of the to-be-tested chip fixture through the testing circuit; and
a joint test action group (JTAG) port, wherein the JTAG port, the testing chip and the to-be-tested chip fixture are serially connected to form a JTAG link through the testing circuit;
a JTAG controller, electrically connected to the JTAG port; and
a testing device, electrically connected to the JTAG controller and configured to generate a testing signal;
wherein the testing device transmits the testing signal to the JTAG controller, the JTAG controller transmits the testing signal to the chip testing circuit board, the chip testing circuit board performs testing on one of the pins of the to-be-tested chip based on the testing signal, and transmits a testing result to the testing device, so as to complete the testing on the pins of the to-be-tested chip.

2. The pin testing system for multi-pin chip according to claim 1, wherein when the testing device determines that the testing signal transmitted to the one of the pins of the to-be-tested chip is the same as the testing result from the one of the pins of the to-be-tested chip, the testing device determines the one of the pins of the to-be-tested chip as normal.

3. The pin testing system for multi-pin chip according to claim 1, wherein when the testing device determines that the testing signal transmitted to the one of the pins of the to-be-tested chip is different from the testing result from the one of the pins of the to-be-tested chip, the testing device determines open-circuit abnormality occurs on the one of the pins of the to-be-tested chip.

4. The pin testing system for multi-pin chip according to claim 1, wherein when the testing device transmits two different testing signals to two of the pins of the to-be-tested chip and the testing results from the two of the pins of the to-be-tested chip are the same, the testing device determines that short-circuit abnormality occurs on the two of the pins of the to-be-tested chip.

5. The pin testing system for multi-pin chip according to claim 1, wherein each of the to-be-tested chip fixture, the testing chip and the JTAG port has a test data input (TDI) pin, a test data output (TDO) pin, a test clock (TCK) pin and a test mode select (TMS) pin, wherein the TCK pins of the to-be-tested chip fixture, the testing chip and the JTAG port are connected to each other, the TMS pins of the to-be-tested chip fixture, the testing chip and the JTAG port are connected to each other, the TDI pin of the JTAG port is connected to the TDI pin of the testing chip, the TDO pin of the testing chip is connected to the TDI pin of the to-be-tested chip fixture, the TDO pin of the to-be-tested chip fixture is connected to the TDO pin of the JTAG port, so that the JTAG port, the testing chip, and the to-be-tested chip fixture are serially connected to form the JTAG link through the testing circuit.

6. A pin testing method for multi-pin chip, comprising:
providing a chip testing circuit board comprising a testing circuit, a to-be-tested chip fixture, a testing chip and a JTAG port;
electrically connecting the to-be-tested chip fixture to the testing circuit, and clamping and fastening a to-be-tested chip, by the to-be-tested chip fixture;
electrically connecting the testing chip to the testing circuit, wherein each of pins of the testing chip is electrically connected to a corresponding one of pins of the to-be-tested chip fixture through the testing circuit;
serially connecting the JTAG port, the testing chip and the to-be-tested chip fixture to form a JTAG link, through the testing circuit;
electrically connecting a JTAG controller to the JTAG port; and
electrically connecting a testing device to the JTAG controller, wherein the testing device is configured to generate a testing signal;
wherein the testing device transmits the testing signal to the JTAG controller, the JTAG controller transmits the testing signal to the chip testing circuit board, the chip testing circuit board performs testing on one of the pins of the to-be-tested chip based on the testing signal, and transmits a testing result to the testing device, so as to complete the testing on the pins of the to-be-tested chip.

7. The pin testing method for multi-pin chip according to claim 6, wherein when the testing device determines that the testing signal transmitted to the one of the pins of the to-be-tested chip is the same as the testing result from the one of the pins of the to-be-tested chip, the testing device determines the one of the pins of the to-be-tested chip as normal.

8. The pin testing method for multi-pin chip according to claim 6, wherein when the testing device determines that the testing signal transmitted to the one of the pins of the to-be-tested chip is different from the testing result from the one of the pins of the to-be-tested chip, the testing device determines open-circuit abnormality occurs on the one of the pins of the to-be-tested chip.

9. The pin testing method for multi-pin chip according to claim 6, wherein when the testing device transmits two different testing signals to two of the pins of the to-be-tested chip and the testing results from the two of the pins of the to-be-tested chip are the same, the testing device determines that short-circuit abnormality occurs on the two of the pins of the to-be-tested chip.

10. The pin testing method for multi-pin chip according to claim 6, wherein each of the to-be-tested chip fixture, the testing chip and the JTAG port has a test data input (TDI) pin, a test data output (TDO) pin, a test clock (TCK) pin and a test mode select (TMS) pin, wherein the TCK pins of the to-be-tested chip fixture, the testing chip and the JTAG port are connected to each other, the TMS pins of the to-be-tested chip fixture, the testing chip and the JTAG port are connected to each other, the TDI pin of the JTAG port is connected to the TDI pin of the testing chip, the TDO pin of the testing chip is connected to the TDI pin of the to-be-tested chip fixture, the TDO pin of the to-be-tested chip fixture is connected to the TDO pin of the JTAG port, so that the JTAG port, the testing chip, and the to-be-tested chip fixture are serially connected to form the JTAG link through the testing circuit.
